(19) United States
(12) Patent Application Publication
(10) Pub. No.: US 2010/0224897 A1
(43) Pub. Date: Sep. 9, 2010

(54) SEMICONDUCTOR OPTOELECTRONIC DEVICE AND METHOD FOR FORMING THE SAME

(75) Inventors: SHIH CHENG HUANG, HSINCHU CITY (TW); CHIH PANG MA, TAOYUAN COUNTY (TW); PO MIN TU, CHIAYI COUNTY (TW); YING CHAO YEH, TAIPEI COUNTY (TW); WEN YU LIN, TAICHUNG COUNTY (TW); PENG YI WU, TAICHUNG CITY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/716,040

(22) Filed: Mar. 2, 2010

(30) Foreign Application Priority Data
Mar. 6, 2009 (TW) 098107246

(51) Int. Cl. H01L 33/02; H01L 21/306

(52) U.S. Cl. 257/98; 438/29; 257/E33.068; 257/E21.219

(57) ABSTRACT

A semiconductor optoelectronic device with enhanced light extraction efficiency includes at least one protrusion structure, which can be formed around a light-emitting region of the device. The at least one protrusion structure can include a plurality of protrusion structures in one embodiment. In addition, a fabricating method for forming a semiconductor optoelectronic device with enhanced light extraction efficiency is provided in the present invention.

### BACKGROUND OF THE INVENTION

1. Field of the Invention

The present invention relates to a semiconductor optoelectronic device and a method of forming the same, and relates more particularly to a semiconductor optoelectronic device having a protrusion structure and a method of fabricating the same.

2. Description of the Related Art

Light emitting diodes are electronic devices which can convert electricity into light and have diode characteristics. Generally, light emitting diodes emit stable light when direct current is supplied; however, light emitting diodes blink when alternating current is supplied, and the blinking frequency is determined by the frequency of the alternating current. The lighting theory of light emitting diodes is that electrons and holes in semiconductor material combine to produce light under an externally applied voltage.

Light emitting diodes have significant advantages of long lifespan, low heat generation, low electrical consumption, energy conservation, and pollution reduction. Light emitting diodes are widely applied; however, the low light emitting efficiency is one problem which still needs to be improved. Due to total reflection and transverse wave propagation phenomena, light generated by current light emitting diodes cannot be completely extracted. The resulting limitation to light emitting efficiency is a hindrance to the popularization of lighting devices using light emitting diodes, and one method to improve the light emitting efficiency of light emitting diodes is to improve the light extraction efficiency of the light emitting diodes.

Taking the example of the light emitting diodes based on gallium nitride, the refractive index of the gallium nitride is 2.5, and that of air is 1. Assuming that light transmits through a uniform optical surface, the calculated critical angle of total reflection is 23.5 degrees. When the incident angle of the light from the light-emitting layer of a GaN light emitting diode is greater than 23.5 degrees, the light is completely reflected back to the interior of the GaN light emitting diode. To date, many techniques have been developed to try to improve the light extraction efficiency, and a surface microstructure processing method is one effective technique to improve the light extraction efficiency. Taiwan Patent No. I296861 discloses a method that forms a rough surface on an n-type cladding layer around a light-emitting region so as to avoid total reflection.

In addition, Taiwan Patent Application No. 200701521, U.S. Pat. No. 6,953,952 B2, U.S. Pat. No. 7,358,544 B2, and U.S. Patent Application No. 2007/0228393 disclose a plurality of protrusions formed at the periphery of and around a light-emitting region. The protrusion has a height similar to that of the light-emitting region, and the angle of the protrusion is between approximately 30 and 80 degrees so as to avoid total reflection. FIG. 1 is a top view showing a traditional semiconductor optoelectronic device of a coplanar electrode configuration. In FIG. 1, a p-type electrode 114 is formed on a light-emitting region 110, and an n-type electrode 115 is formed beside the light-emitting region 110. A plurality of protrusions 122 are on the device-dicing surface 124, surrounding the light-emitting region 110 and the n-type electrode 115. A plurality of gaps 123 is disposed among the plurality of protrusions 122. Because light is directionless and photons are distributively disposed on the light-emitting region 110, a majority of the light can be directed to emit externally by changing the reflection angle of the light using the angle and height of the protrusion 122. However, the photons may be not allowed to pass through the gaps 123, reflecting in total reflection or refracting, and generating heat.

Thus, the present invention proposes a new approach to resolve the above-mentioned issues so as to improve the light extraction efficiency of a semiconductor optoelectronic device.

### SUMMARY OF THE INVENTION

According to the discussion in the Description of the Related Art and to meet the requirements of industry, the present invention provides a semiconductor optoelectronic device, which comprises a protrusion structure disposed around its light-emitting region.

The present invention provides a semiconductor optoelectronic device with enhanced light extraction efficiency, which comprises a substrate, a light emitting region, and at least one protrusion structure, wherein the at least one protrusion structure is formed on a device-dicing surface, separated from the light emitting region by a groove, and disposed around the light emitting region.

The light-emitting region comprises an n-type conduction layer formed on the substrate, a light emitting layer formed on the n-type conduction layer, and a p-type conduction layer formed on the light-emitting layer.

A buffer layer can be formed between the substrate and the n-type conduction layer. An electron-blocking layer can be formed between the light emitting layer and the p-type conduction layer. A transparent conductive layer can be formed on the light-emitting region. An n-type electrode is formed on the n-type conduction layer. A p-type electrode is formed on the transparent conductive layer. A protection layer is finally formed to cover the light emitting region but exposes the p-type electrode, or is formed to cover the light emitting region and the protrusion structure but exposes the n-type and p-type electrodes.

The protrusion structure and the light-emitting region are separated by a groove having a width of between 0.1 and 10 micrometers.

The side surface of the protrusion structure can be an inclined surface inclined at an angle of from 45 to 90 degrees, preferably between 65 and 80 degrees. The protrusion structure can have a trapezoidal or triangular cross section.

The height of the protrusion structure can be between that of the p-type conduction layer and that of the n-type conduction layer, and the width of the protrusion structure can be in a range of from 0.1 to 10 micrometers.

Further, the present invention provides a fabricating method for forming a semiconductor optoelectronic device with enhanced light extraction efficiency comprising the steps of: providing a substrate; forming a light emitting structure on said substrate; etching said light emitting structure peripherally to form a light emitting region, a device-dicing surface, and a protrusion structure formed on the device-dicing surface. The protrusion structure is separated from the light-emitting region by a groove and disposed around the light-emitting region.

A buffer layer can be formed between the substrate and the n-type conduction layer. An electron-blocking layer can be formed between the light emitting layer and the p-type conduction layer. A transparent conductive layer can be formed on the light-emitting region. An n-type electrode is formed on the n-type ohmic contact layer. A p-type electrode is formed on the transparent conductive layer. A protection layer is finally formed to cover the light emitting region while exposing the p-type electrode, or is formed to cover the light emitting region and the protrusion structure while exposing the n-type and p-type electrodes.

The above-mentioned structure allows light to be directly emitted outside through the p-type conduction layer, and to reflect or refract outside through the protrusion structure from the interior of the structure. The protrusion structure surrounds the light-emitting region so as to increase the possibility of light passing therethrough, reduce internal energy consumption, and increase light extraction efficiency.

To better understand the above-described objectives, characteristics and advantages of the present invention, embodiments, with reference to the drawings, are provided for detailed explanations.

### BRIEF DESCRIPTION OF THE DRAWINGS

The invention will be described according to the appended drawings in which:

FIG. 1 is a top view showing a traditional semiconductor optoelectronic device of a coplanar electrode configuration;

FIG. 2 is a top view showing a semiconductor optoelectronic device of a coplanar electrode configuration having a single protrusion structure;

FIGS. 3A to 3G are cross sections taken along line A-A′ in FIG. 2 showing a fabricating method for forming a semiconductor optoelectronic device with enhanced light extraction efficiency according to one embodiment of the present invention;

FIG. 4 is a top view showing a semiconductor optoelectronic device of a coplanar electrode configuration having a plurality of protrusion structures according to one embodiment of the present invention;

FIG. 5 is a cross-sectional view along line B-B′ of FIG. 4;

FIG. 6A is an enlarged view showing a protrusion structure according to one embodiment of the present invention;

FIG. 6B is a view showing a protrusion structure according to one embodiment of the present invention;

FIG. 7 is a top view showing a semiconductor optoelectronic device of a double-sided electrode configuration having a single protrusion structure according to one embodiment of the present invention;

FIG. 8 is a cross-sectional view taken along line C-C′ of FIG. 7;

FIG. 9 is a top view showing a semiconductor optoelectronic device of a double-sided electrode configuration having a plurality of protrusion structures according to one embodiment of the present invention;

FIG. 10 is a cross-sectional view taken along line D-D′ of FIG. 9;

FIGS. 11A to 11G are cross-sectional views showing a fabricating method for forming a semiconductor optoelectronic device of separated coplanar electrode type having a plurality of protrusion structures according to one embodiment of the present invention;

FIG. 12 shows the luminous intensity distribution curves of the semiconductor optoelectronic device of one embodiment of the present invention and of the conventional semiconductor optoelectronic device; and

FIG. 13 is a diagram showing brightness gain vs. the inclined angle of side surface for different quantities of protrusion structures.

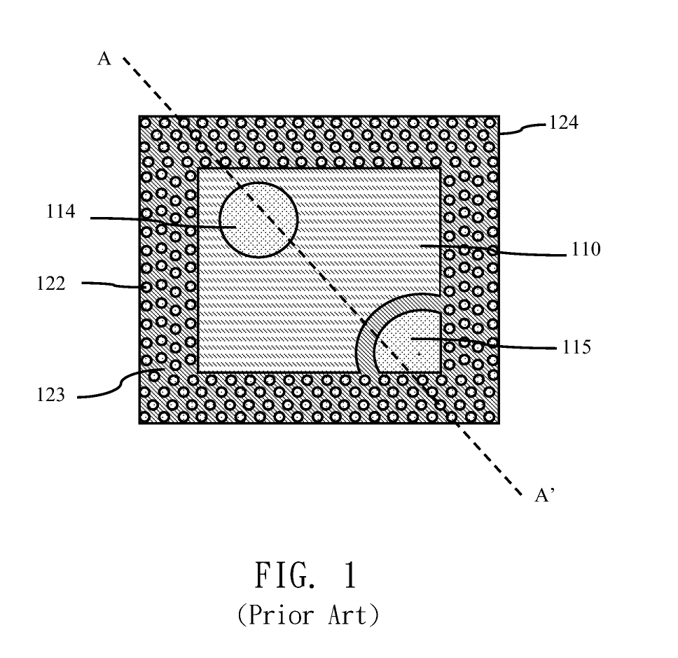

### DETAILED DESCRIPTION OF THE INVENTION

The present invention exemplarily demonstrates embodiments of a semiconductor optoelectronic device with enhanced light extraction efficiency and a fabricating method for forming the same. In order to thoroughly understand the present invention, detailed descriptions of method steps and components are provided below. Clearly, the implementations of the present invention are not limited to the specific details that are familiar to persons in the art related to optoelectronic semiconductor manufacturing processes to avoid unnecessary limitations to the present invention. On the other hand, components or method steps, which are well known, are not described in detail. A preferred embodiment of the present invention will be described in detail as follows. However, in addition to the preferred detailed description, other embodiments can be broadly employed, and the scope of the present invention is not limited by any of the embodiments, but should be defined in accordance with the following claims and their equivalents.

The embodiments of the present invention use an etching process to form at least one protrusion structure and a light emitting region after a semiconductor optoelectronic structure is formed using an epitaxial process. The at least one protrusion structure is separated from the light emitting region by a groove, and disposed around the light emitting region.

Due to the directionless propagation of light, light generated by the light-emitting layer of the light-emitting region can not only be transmitted through and out of the p-type conduction layer, but also transmitted in an internal direction or a lateral direction out of a semiconductor optoelectronic device. The light, reflected internally and then refracted through and out of the at least one protrusion structure, can not only increase the luminance of the semiconductor optoelectronic device, but also improves the light extraction efficiency.

According to one embodiment of the present invention, a semiconductor optoelectronic device with enhanced light extraction efficiency comprises a substrate, a light emitting region, and at least one protrusion structure, wherein the protrusion structure is formed on a device-dicing surface, separated from the light emitting region by a groove, and disposed around the light emitting region.

The light-emitting region comprises an n-type conduction layer formed on the substrate, a light emitting layer formed on the n-type conduction layer, and a p-type conduction layer formed on the light-emitting layer.

Between the substrate and the n-type conduction layer, a buffer layer can be formed. Between the light emitting layer and the p-type conduction layer, an electron-blocking layer can be formed. A transparent conductive layer can be formed on the light-emitting region. An n-type electrode can be formed on the n-type conduction layer. A p-type electrode is formed on the transparent conductive layer. Finally, a protection layer covers the light emitting region, but exposes the p-type electrode, or covers the light emitting region and the at least one protrusion structure, but exposes the p-type electrode and the n-type electrode.

The above-mentioned substrate can be a sapphire (Al₂O₃) substrate, a silicon carbide (SiC) substrate, a lithium aluminate (LiAlO₂) substrate, a lithium gallate (LiGaO₂) substrate, a silicon substrate, a gallium nitride (GaN) substrate, a zinc oxide (ZnO) substrate, an aluminum zinc oxide (AlZnO) substrate, a gallium arsenide (GaAs) substrate, a gallium phosphide (GaP) substrate, a gallium antimonide (GaSb) substrate, an indium phosphide (InP) substrate, an indium arsenide (InAs) substrate, or a zinc selenide (ZnSe) substrate.

The above-mentioned buffer layer can be of gallium nitride, aluminum gallium nitride, aluminum nitride, or InₓGa₁₋ₓN/In_{y}Ga_{1-y}N supperlattice material, wherein x≠y.

The n-type conduction layer may comprise silicon dopant, and the p-type may comprise magnesium dopant.

The transparent conductive layer may be nickel-gold (Ni/Au) alloy, indium tin oxide, indium zinc oxide, indium tungsten oxide, or indium gallium oxide.

The n-type electrode is electrically connected to the n-type conduction layer, and the p-type electrode is electrically connected to the p-type conduction layer.

The above-mentioned protection layer can be of silicon oxide (SiO₂) or silicon nitride (Si₃N₄).

The at least one protrusion structure and the light emitting region are separated from one another by a groove. The at least one protrusion structure may comprise a plurality of protrusion structures, which are also separated from one another by a groove. The aforementioned groove can have a width in a range of from 0.1 to 10 micrometers.

The side surface of the protrusion structure can be an inclined surface inclined at an angle of from 45 to 90 degrees. Preferably, the side surface can be inclined at an angle of from 65 to 80 degrees. Further, the protrusion structure can include a trapezoidal or triangular cross section.

The protrusion structure can protrude between the p-type conduction layer and the n-type conduction layer. The protrusion structure can have a width of from 0.1 to 10 micrometers.

Furthermore, the present invention proposes a fabricating method for forming a semiconductor optoelectronic device with enhanced light extraction efficiency. The method comprises the steps of: providing a substrate; forming a light emitting structure on the substrate; etching the light emitting structure peripherally to form a light emitting region, a device-dicing surface, and a protrusion structure on the device-dicing surface. The protrusion structure is separated from the light-emitting region by a groove, and is disposed around the light-emitting region.

The above-mentioned light emitting structure may comprise an n-type conduction layer formed on the substrate, a light-emitting layer formed on the n-type conduction layer, and a p-type conduction layer formed on the light-emitting layer.

Between the substrate and the n-type conduction layer, a buffer can be formed. Between the light emitting layer and the p-type conduction layer, an electron-blocking layer can be formed. A transparent conductive layer can be formed on the light-emitting region. An n-type electrode can be formed on the n-type conduction layer, and a p-type electrode can be formed on the transparent conductive layer. Finally, a protection layer covers the light emitting region, but exposes the p-type electrode, or covers the light emitting region and the at least one protrusion structure, but exposes the p-type electrode and the n-type electrode.

The above-mentioned forming steps are explained by the following figures each showing the corresponding structure and the descriptions describing the corresponding figure.

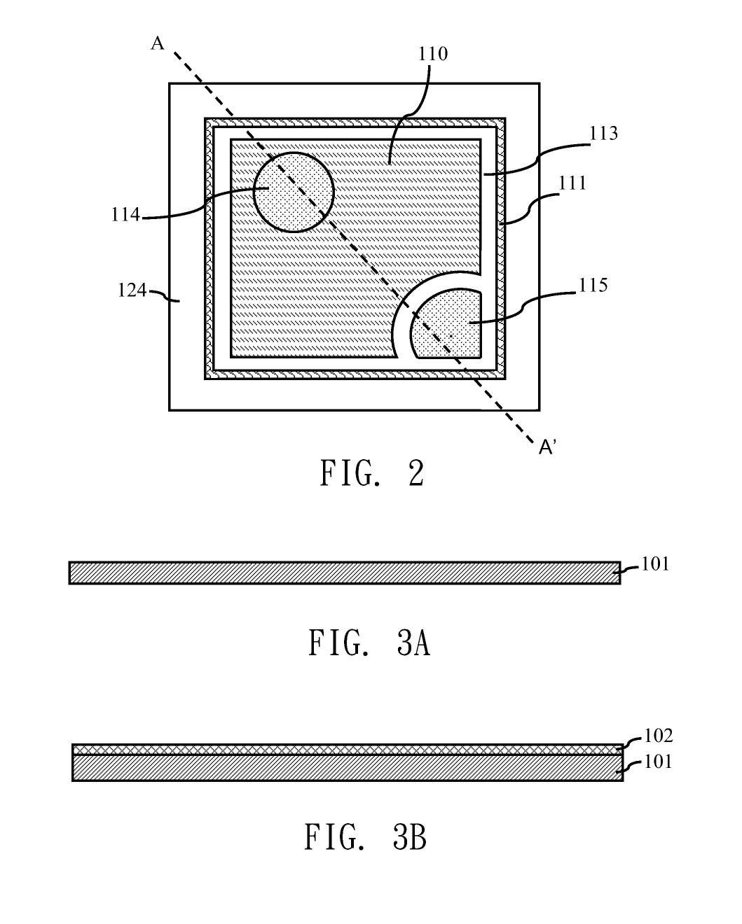

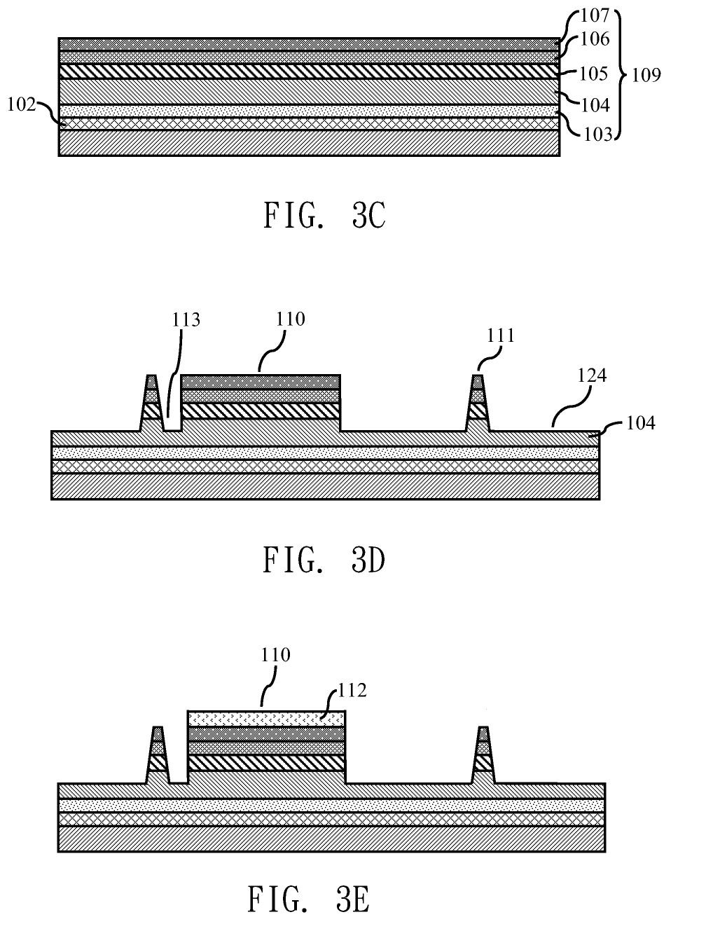

The inventor provides a semiconductor optoelectronic device with enhanced light extraction efficiency. FIG. 2 is a top view showing a semiconductor optoelectronic device of a coplanar electrode configuration having a single protrusion structure. On the light-emitting region 110 of the semiconductor optoelectronic device, a p-type electrode 114 is formed. Next to the light emitting region 110, an n-type electrode 115 is formed. A protrusion structure 111 is disposed on the device-dicing surface 124, separated from the light-emitting region 110 and from the n-type electrode 115 by a groove 113, and disposed around the light emitting region 110 and the n-type electrode 115. FIGS. 3A to 3G are cross sections along line A-A′ of FIG. 2, and each cross section demonstrates the structure formed in the corresponding process step.

As shown in FIG. 3A, the surfaces of a substrate 101 are cleaned. A substrate 101 such as a sapphire (Al₂O₃) substrate, a silicon carbide (SiC) substrate, a lithium aluminate (LiAlO₂) substrate, a lithium gallates (LiGaO₂) substrate, a silicon substrate, a gallium nitride (GaN) substrate, a zinc oxide (ZnO) substrate, an aluminum zinc oxide (AlZnO) substrate, a gallium arsenide (GaAs) substrate, a gallium phosphide (GaP) substrate, a gallium antimonide (GaSb) substrate, an indium phosphide (InP) substrate, an indium arsenide (InAs) substrate, or a zinc selenide (ZnSe) substrate is provided. The cleaning of the substrate 101 can be performed by a thermal cleaning process in which the substrate 101 is exposed in a hydrogen environment at 1200 degrees Celsius, and ammonia gas and an organic metal precursor are introduced. The organic metal precursor can be an aluminum organic metal precursor such as trimethylaluminum and triethylaluminum, a gallium organic metal precursor such as trimethylgallium and triethylgallium, or an indium organic metal precursor such as trimethylindium and triethylindiuim.

As shown in FIG. 3B, a buffer layer 102 is formed on the substrate 101. The lattice structure and lattice constant are important factors for selection of an epitaxial substrate. If the difference between the lattice constants of a substrate and an epitaxial layer is too great, a buffer layer is required to obtain an epitaxial layer of better quality. The buffer layer 102 can be formed using a chemical vapor deposition process performed by a metal organic chemical vapor deposition equipment or a molecular beam epitaxy equipment so that the epitaxial layer can be grown at a lower temperature compared to a normal epitaxial layer growing process performed later. For example, aluminum gallium indium nitride layer is normally grown at a temperature between 800 and 1400 degrees Celsius; however, the buffer layer 102 is grown at a temperature between 250 and 700 degrees Celsius. When a metal organic chemical vapor deposition process is applied, the nitrogen precursor can be ammonia (NH₃) or nitrogen; the gallium precursor can be trimethylgallium or triethylaliuminum; the aluminum precursor can be trimethylaluminum or triethylaluminum; and the indium precursor can be trimethylindium or triethylindium. The reactor may be maintained at low pressure or ambient pressure. The buffer layer 102 can be of gallium nitride, aluminum gallium nitride, aluminum nitride, or InₓGa₁₋ₓN/In_{y}Ga_{1-y}N supperlattice material, wherein the buffer layer made of aluminum nitride is disclosed in a patent assigned to TOYODA GOSEI CO., LTD; the buffer layer made of aluminum gallium nitride is disclosed in a patent assigned to Nichia Corporation; and the buffer layer made of InₓGa₁₋ₓN/In_{y}Ga_{1-y}N supperlattice material is disclosed in a patent application assigned to Advanced Optoelectronic Technology, Inc. Regarding the formation of the buffer layer made of InₓGa₁₋ₓN/In_{y}Ga_{1-y}N supperlattice material; please refer to Taiwan Patent Application No. 096104378.

As shown in FIG. 3C, after formation of the buffer layer 102, a light emitting structure 109 is epitaxially formed on the buffer layer 102. To improve the quality of the grown epitaxial lattice of the light emitting structure, a non-doped gallium nitride layer 103 or aluminum gallium nitride layer can be formed on the buffer layer 102 in advance. After formation of a non-doped gallium nitride layer 103, group IV atoms are implanted to form an n-type conduction layer 104. In the present embodiment, the group IV atom can be a silicon atom. The silicon precursor in the metal organic chemical vapor deposition equipment can be silane (SiH₄) or disilane (Si₂H₆). The n-type conduction layer 104 is sequentially composed of a gallium nitride layer or an aluminum gallium nitride doped with highly concentrated silicon and a gallium nitride layer or an aluminum gallium nitride doped with minimally concentrated silicon. The gallium nitride layer or the aluminum gallium nitride doped with highly concentrated silicon can provide the n-type electrode with better electrical conductivity.

Thereafter, a light emitting layer 105 is formed on the n-type conduction layer, wherein the light emitting layer 105 can be a single hetero-structure, a double hetero-structure, a single quantum well layer, or a multiple quantum well layer. Presently, a multiple quantum well layer structure, namely a multiple quantum well layer/barrier layer structure, is adopted. The quantum well layer can be of indium gallium nitride, and the barrier layer can be made of a ternary alloy such as aluminum gallium nitride. Further, a quaternary alloy such as AlₓIn_{y}Ga_{1-x-y}N can be used for formation of the quantum well layer and the barrier layer, wherein the barrier layer with a wide band gap and the quantum well layer with a narrow band gap can be obtained by adjusting the concentrations of aluminum and indium in the aluminum indium gallium nitride. The light-emitting layer 105 can be doped with an n-type or p-type dopant, or can be doped with an n-type and p-type dopants simultaneously, or can include no dopant. In addition, the quantum well layer can be doped and the barrier layer can be not doped; the quantum well layer can be not doped and the barrier layer can be doped; both the quantum well layer and the barrier layer can be doped; or neither of the quantum well layer and the barrier layer can be doped. Further, a portion of the quantum well layer can be delta-doped.

Next, an electron barrier layer 106 with p-type conduction is formed on the light-emitting layer 105. The electron barrier layer 106 with p-type conduction may comprise a first Group III-V semiconductor layer and a second Group III-V semiconductor layer. The first and second Group III-V semiconductor layers can have two different band gaps, and are periodically and repeatedly deposited on the light-emitting layer 105. The periodical and repeated deposition process can form an electron barrier layer having a wider band gap, which is higher than that of the active light emitting layer, so as to block excessive electrons overflowing from the light emitting layer 105. The first Group III-V semiconductor layer can be an aluminum indium gallium nitride (AlₓIn_{y}Ga_{1-x-y}N) layer. The second Group III-V semiconductor layer can be an aluminum indium gallium nitride (AlᵤInᵥGa₁₋ᵤ₋ᵥN) layer, wherein 0<x≦1, 0≦y<1, x+y≦1, 0≦u<1, 0≦v≦1, and u+v≦1. When x is equal to u, y is not equal to v. Further, the first and second Group III-V semiconductor layers can be of gallium nitride, aluminum nitride, indium nitride, aluminum gallium nitride, indium gallium nitride, or aluminum indium nitride.

Finally, a Group II atom is doped to form a p-type conduction layer 107 on the electron barrier layer 106. In the present embodiment, the Group II atom can be a magnesium atom. The magnesium precursor in the metal organic chemical vapor deposition equipment can be CP₂Mg. The p-type conduction layer 107 is sequentially composed of a gallium nitride layer or an aluminum gallium nitride doped with minimally concentrated magnesium and a gallium nitride layer or an aluminum gallium nitride doped with highly concentrated magnesium. The gallium nitride layer or the aluminum gallium nitride doped with highly concentrated magnesium can provide the p-type electrode with better electrical conductivity.

As shown in FIG. 3D, after the epitaxial process, a photoresist film is completely formed on the surface of the light emitting structure 109 by centrifugally spinning photoresist on the surface using a photoresist coater. Next, the photoresist film is patterned using a photolithography process to obtain a mask such that a portion of the light emitting structure 109 is exposed for etching. Inductively coupled plasma etcher is used to etch out a light emitting region 110, at least one protrusion structure 111, and a device-dicing surface 124, and to expose the n-type conduction layer 104. Next, the photoresist film is finally removed. The protrusion structure 111 is located on the device-dicing surface 124, separated from the light emitting region 110 by a groove 113, and disposed around the light-emitting region 110. The plurality of protrusion structures 111 are separated from one another by grooves 113, and are disposed around the light emitting region 110 in a parallel manner.

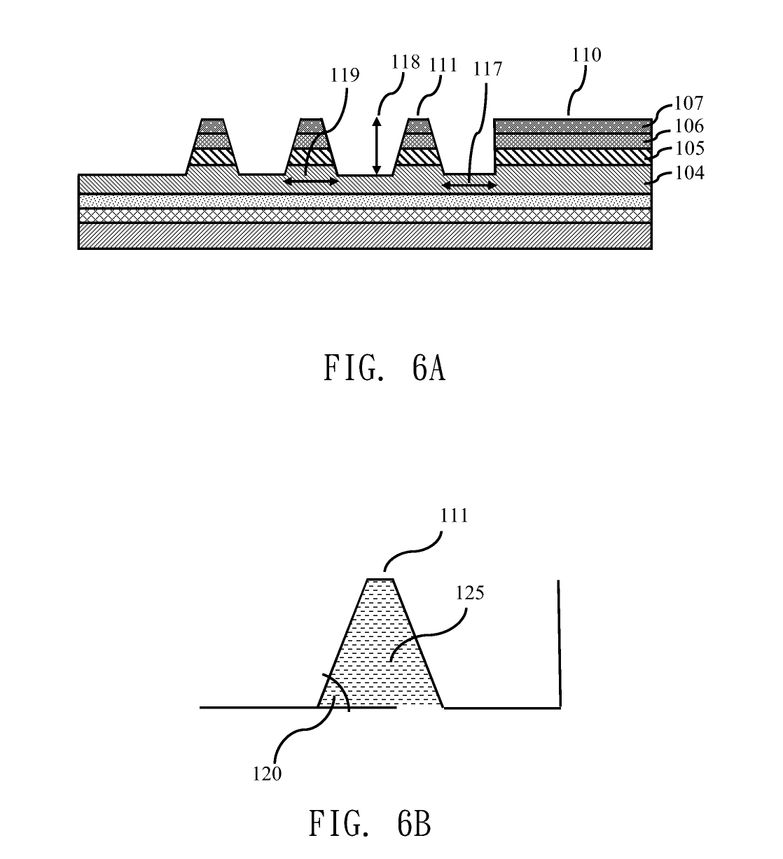

The characteristics of the protrusion structure 111 are further explained in the following description. FIG. 6A is an enlarged view showing a protrusion structure 111 according to one embodiment of the present invention. Each of the grooves between the protrusion structure 111 and the light-emitting region 110, and between the plurality of protrusion structures 111, can have a width 117 of from 0.1 to 10 micrometers. The width of protrusion structure 119 can be of from 0.1 to 10 micrometers. The height 118 of the protrusion structure 111 is between that of the p-type conduction layer and that of the n-type conduction layer. FIG. 6B is a view showing a protrusion structure according to one embodiment of the present invention. The side surface of the protrusion structure is an inclined surface, and the side surface can be inclined at an angle “A” 120 in a range of from 45 to 90 degrees. Preferably, the side surface can be inclined at an angle in a range of from 65 to 80 degrees. The protrusion structure can have a trapezoidal or triangular cross section.

As shown in FIG. 3E, after the light emitting region 110 and the protrusion structure 111 are etched out, a transparent conductive layer 112 is then formed on the light emitting region 110. The transparent conductive layer 112 can have high transmission rate and high electrical conductivity so that light can transmit therethrough and electrical current can be uniformly dispersed. Generally, the transparent conductive layer 112 can be formed on the light emitting region 110 using physical vapor deposition such as evaporation or sputtering. The material of the transparent conductive layer 112 can be nickel gold alloy, indium tin oxide, indium zinc oxide, indium tungsten oxide, or indium gallium oxide.

As shown in FIG. 3F, a p-type electrode 114 is formed on the transparent conductive layer 112 and electrically connected to the p-type conduction layer 107, and an n-type electrode 115 is electrically connected to the n-type conduction layer 104. The material of the p-type electrode 114 can be nickel gold alloy, platinum gold alloy, tungsten, chrome-gold alloy, or palladium. The material of the n-type electrode can be titanium/aluminum/titanium/gold, chrome-gold alloy, or lead-gold alloy.

As shown in FIG. 3G, a protection layer 116 is finally formed. The protection layer 116 can cover the light emitting region 110 but exposes the p-type electrode 114; or can cover the light emitting region 110 and the protrusion structure 111 but expose the p-type electrode 114 and the n-type electrode 115. The protection layer 116 protects the light-emitting region 110 from external pollutants which can cause the semiconductor optoelectronic device to fail. The material of the protection layer 116 can be silicon oxide or silicon nitride.

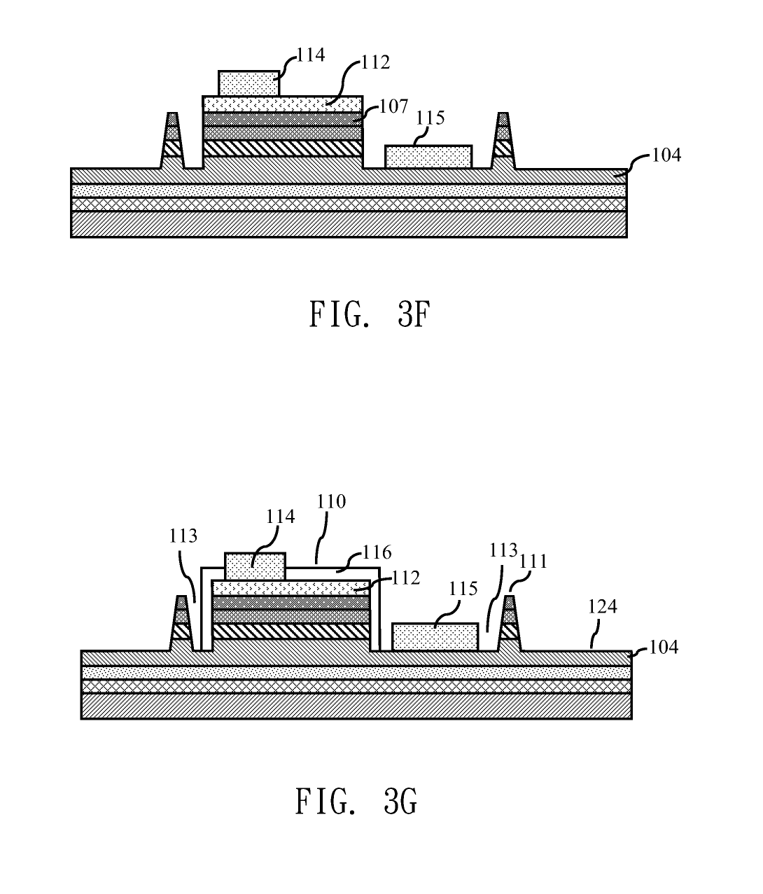

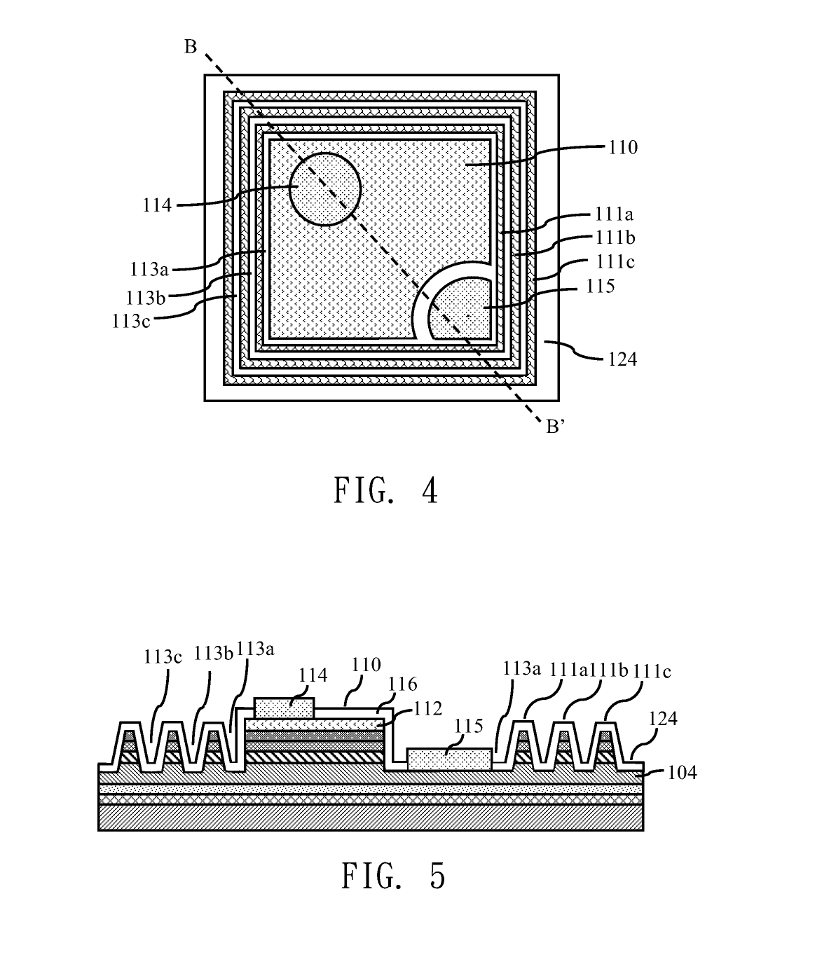

The at least one protrusion structure disclosed in the present invention may comprise a plurality of protrusion structures, which are parallel layered around the light emitting region. FIG. 4 is a top view showing a semiconductor optoelectronic device of a coplanar electrode configuration having a plurality of protrusion structures according to one embodiment of the present invention. The semiconductor optoelectronic device comprises a light emitting region 110, a p-type electrode 114 formed on the light emitting region 110, an n-type electrode 115 formed beside the light emitting region 110, and a plurality of protrusion structures 111a, 111b, and 111c disposed adjacent to the n-type electrode 115 and the light emitting region 110. The plurality of protrusion structures 111a, 111b, and 111c are formed on the device-dicing surface 124. The protrusion structure 111a is separated from the light-emitting region 110 by a groove 113a. Between the protrusion structures 111b and 111c, a plurality of grooves 113b and 113c are disposed in order to separate the protrusion structures 111b and 111c from each other. The plurality of protrusion structures 111a, 111b, and 111c are disposed around the light emitting region 110 and the n-type electrode 115 in a parallel manner. The quantity of the protrusion structures is not limited. A protection layer 116 is formed to cover the light emitting region 110 and the plurality of protrusion structures 111a, 111b, and 111c, but exposes the p-type electrode 114 and the n-type electrode 115; or the protection layer 116 is formed to cover the light emitting region 110, but exposes the p-type electrode 114.

Generally, the substrate 101 can be a sapphire (Al₂O₃) substrate; however, the sapphire substrate has disadvantages such as poor electrical conductivity and low heat dissipation efficiency, which may detrimentally affect the reliability of the semiconductor optoelectronic device. To avoid the factors affecting the reliability of the semiconductor optoelectronic device, a substrate such as a silicon carbide (SiC) substrate, a silicon substrate, a gallium nitride (GaN) substrate, a gallium arsenide (GaAs) substrate, a gallium phosphide (GaP) substrate, a gallium antimonide (GaSb) substrate, an indium phosphide (InP) substrate, an indium arsenide (InAs) substrate, or a zinc selenide (ZnSe) substrate, having better electrical conductivity and heat dissipation efficiency is preferably used to form a semiconductor optoelectronic device of a double-sided electrode configuration.

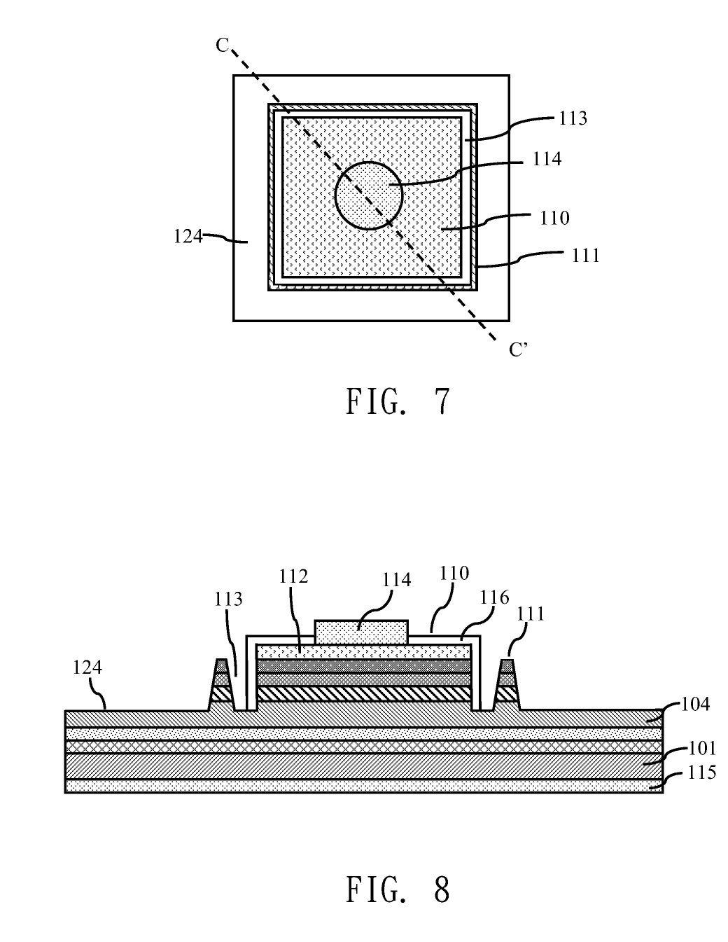

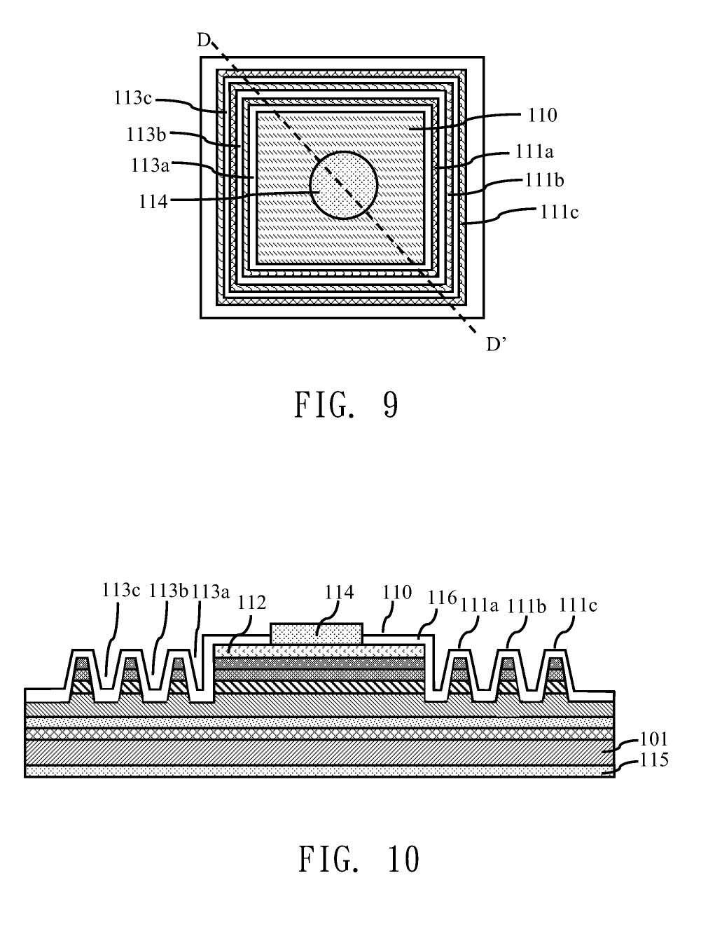

FIG. 7 is a top view showing a semiconductor optoelectronic device of a double-sided electrode configuration having a single protrusion structure according to one embodiment of the present invention. On a light-emitting region 110, a p-type electrode 114 is formed. A protrusion structure 111 is formed on a device-dicing surface 124, separated from the light emitting region 110 by a groove 113, and disposed around the light-emitting region 110. FIG. 8 is a cross-sectional view taken along line C-C′ of FIG. 7. A transparent conductive layer 112 is formed on a light-emitting region 110. A p-type electrode 114 is formed on the transparent conductive layer 112. A protrusion structure 111 is disposed on a device-dicing surface 124, is separated from the light-emitting region 110 by a groove 113, and is disposed around the light-emitting region 110. An n-type is disposed below the substrate 101.

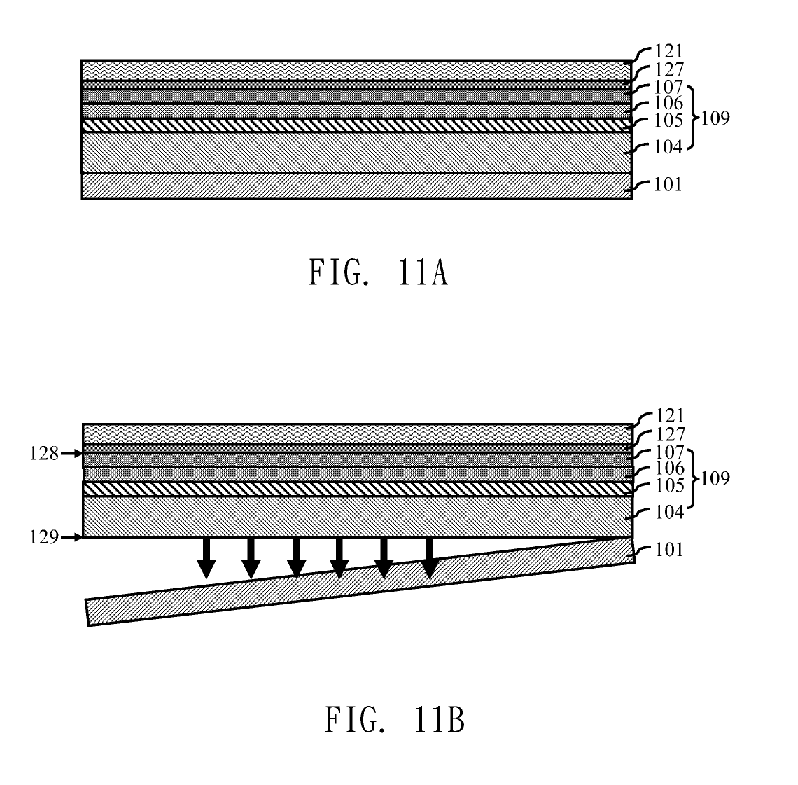

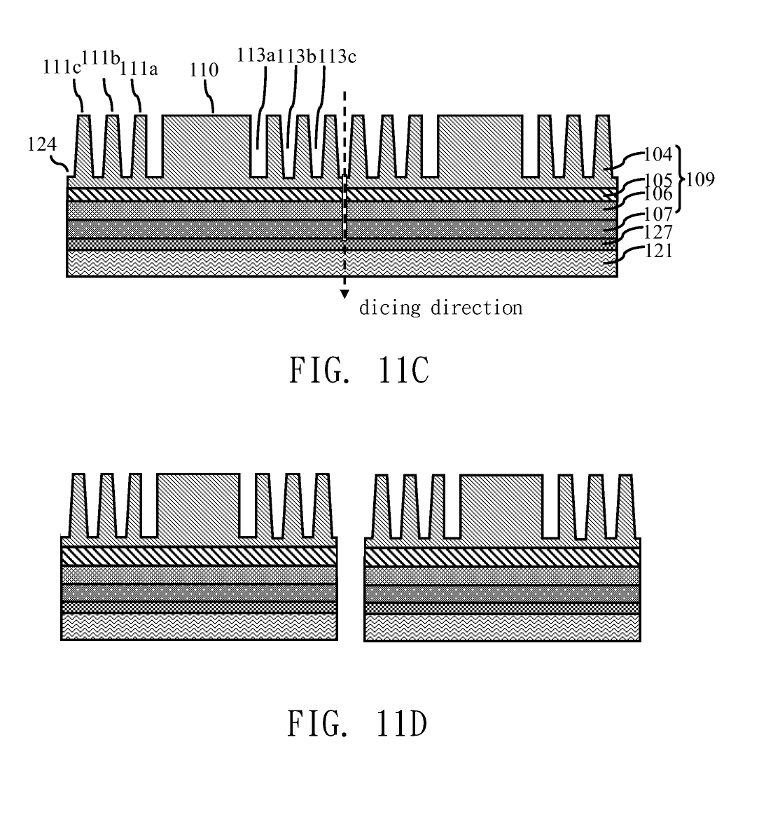

In addition, the semiconductor optoelectronic device of a double-sided electrode configuration may comprise a plurality of protrusion structures. FIG. 9 is a top view showing a semiconductor optoelectronic device of a double-sided electrode configuration having a plurality of protrusion structures according to one embodiment of the present invention. The semiconductor optoelectronic device of a double-sided electrode configuration having a plurality of protrusion structures comprises a light emitting region 110, a p-type electrode 114 formed on the light emitting region 110, and a plurality of protrusion structures 111a, 111b, and 111c formed on a device-dicing surface 124. The first protrusion structure 111a and the light emitting region 110 are separated by a groove 113a; the first protrusion structure 111a and the second protrusion structure 111b are separated by a groove 113b; and the second protrusion structure 111b and the third protrusion structure 111c are separated by a groove 113c. The plurality of protrusion structures 111a, 111b, and 111c are disposed around the light-emitting region 110 in a parallel manner. FIG. 10 is a cross-sectional view taken along line D-D′ of FIG. 9. It can be clearly seen in the cross section of FIG. 10 that a transparent conductive layer 112 is formed on the light emitting region 110, a p-type electrode 114 is formed on the transparent conductive layer 112, and a plurality of protrusion structures 111a, 111b, and 111c are formed on a device-dicing surface 124. The first protrusion structure 111a and the light-emitting region 110 are separated by a groove 113a. The plurality of protrusion structures 111a, 111b, and 111c are separated by grooves 113b and 113c, and are disposed around the light-emitting region 110 in a parallel manner. The quantity of the protrusion structures may not be limited. A protection layer 116 can cover both the light emitting region 110 and the plurality of protrusion structures 111a, 111b, and 111c while exposing the p-type electrode; or a protection layer 116 can cover only the light-emitting region 110 exposing the p-type electrode 114. An n-type electrode is disposed below the substrate 101.

The process of epitaxially growing a semiconductor layer may cause the semiconductor layer to exhibit threading dislocation and thermal stress issues because the lattice constant and the thermal expansion coefficient of the semiconductor layer and the heterogeneous substrate are different. Thus, the present invention provides another fabricating method in which a substrate separation technique is applied to mitigate the above-mentioned issues so as to increase the stability of a semiconductor optoelectronic device.

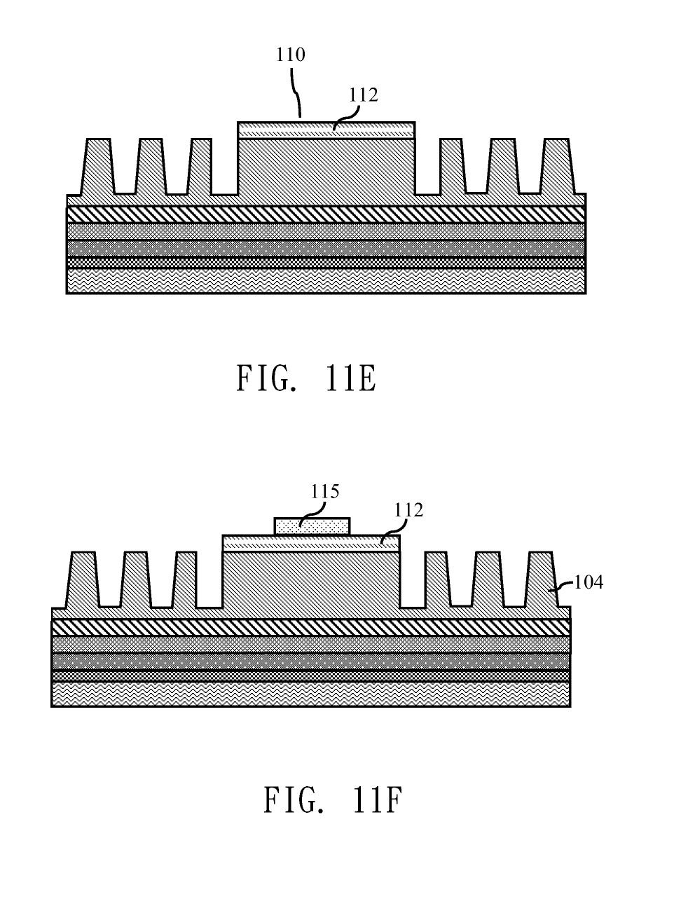

The below-mentioned substrate separation methods are disclosed in patent applications assigned to Advanced Optoelectronic Technology, Inc. The substrate and the light emitting structure are initially separated, and a light emitting region and at least one protrusion structure are formed using an etching process. The process steps of fabricating a semiconductor optoelectronic device with enhanced light extraction efficiency are shown in FIGS. 11A to 11G. The process steps begin with an etching process, and to avoid redundancy, the substrate separation technique is not described herein.

The first substrate separation method initially grows a first Group III nitride compound semiconductor layer on a surface of a temporary substrate. The first Group III nitride compound semiconductor layer can be patterned using lithographic and etching processes. A second Group III nitride compound semiconductor layer is formed on the first Group III nitride compound semiconductor layer. A conductive layer is formed on the second Group III nitride compound semiconductor layer. The combination of the second Group III nitride compound semiconductor layer and the conductive layer can be obtained by separating the combination from the temporary substrate using the first Group III nitride compound semiconductor layer. The details and steps of the separation process used in the first substrate separation method are described in Taiwan Patent Application No. 097107609 assigned to Advanced Optoelectronic Technology, Inc.

The second substrate separation method initially grows a first Group III nitride compound semiconductor layer on a surface of a primary substrate. An epitaxial blocking layer is formed on the first Group III nitride compound semiconductor layer. A second Group III nitride compound semiconductor layer is formed on the epitaxial blocking layer and the uncovered portion of the first Group III nitride compound semiconductor layer. The epitaxial blocking layer is removed. A third Group III nitride compound semiconductor layer is formed on the second Group III nitride compound semiconductor layer. A conductive layer is deposited on the third Group III nitride compound semiconductor layer. Finally, the third Group III nitride compound semiconductor layer and the structure thereon are separated from the second Group III nitride compound semiconductor layer. The details and steps of the separation process used in the second substrate separation method are described in Taiwan Patent Application No. 097115512 assigned to Advanced Optoelectronic Technology, Inc.

The third substrate separation method initially forms a mask on a substrate, and the mask is annealed to obtain a plurality of pillar elements. A plurality of pillar elements is formed on the substrate by etching the substrate via the gaps between the plurality of mask elements. The plurality of mask elements is separated from the substrate to obtain a substrate with a plurality of pillar elements, wherein the plurality of the pillar elements can be a pillar element array. Thereafter, a semiconductor layer is formed on the pillar element array, and the pillar element array is wet-etched to separate the semiconductor layer and the substrate so as to obtain a freestanding block material or a thin film. The details and steps of the separation process used in the second substrate separation method are described in Taiwan Patent Application No. 097117099 assigned to Advanced Optoelectronic Technology, Inc.

The process method provided by the present invention and subsequent to the second substrate separation method, is described as follows. Referring to FIGS. 11A and 11B, a conductive layer 121 is formed on the first surface 128 of the light emitting structure 109 using an electroplating or composite-electroplating method. Between the light emitting structure 109 and the conductive layer 121, a gold layer 127 can be formed. Next, the substrate 101 and the light emitting structure 109 are separated so as to expose a second surface 129 of the light emitting structure 109 opposite the first surface 128. The material of the conductive layer 121 can be copper, nickel, or copper-tungsten alloy. The light emitting structure 109 may comprise an n-type conduction layer, a light emitting layer 105, an electron blocking layer 106, and a p-type conduction layer 107, wherein the first surface 128 of the light emitting structure 109 is that of the p-type conduction layer 107, and the second surface 129 opposite the first surface 128 is that of the n-type conduction layer 104.

Referring to FIGS. 11C and 11D, a photoresist film is formed on the surface of the light emitting structure by centrifugally spinning photoresist on the surface using a photoresist coater. A mask is formed by patterning the photoresist film using photolithography so that the portions for etching can be exposed. Inductively coupled plasma etcher is used to etch out a light emitting region 110, a plurality of protrusion structures 111a, 111b, and 11c, a plurality of grooves 113a, 113b, and 113c, and a device-dicing surface 124, and to expose the n-type conduction layer 104. Simultaneously, optoelectronic chips are separated from each other so that they can be diced for separation. Finally, the photoresist film is removed. The protrusion structure 111a and the light-emitting region 110 are separated by a groove 113a. The protrusion structures 111a, 111b, and 111c are separated by the plurality of grooves 113b and 113c, and disposed around the light-emitting region 110 in a parallel manner. The quantity of the protrusion structures is not limited.

The requirements of the protrusion structure 111 are similar to those of the protrusion structure in the semiconductor optoelectronic devices of a coplanar electrode configuration and of a double-sided electrode configuration. FIG. 6A is an enlarged view showing a protrusion structure according to one embodiment of the present invention. The width 117 of the grooves between the protrusion structure 111 and the light-emitting region 110, and between the plurality of protrusion structures 111, is in a range of from 0.1 to 10 micrometers. The width 119 of the protrusion structure 111 is in a range of from 0.1 to 10 micrometers. The height 118 of the protrusion structure is between that of the p-type conduction layer and that of the n-type conduction layer. FIG. 6B is a schematic view showing a protrusion structure according to one embodiment of the present invention. The side surface of the protrusion structure can be an inclined surface, which is inclined at an angle of from 45 to 90 degrees, and preferably, at an angle of from 65 to 80 degrees. The protrusion structure can include a trapezoidal or triangular cross section.

Referring to FIG. 11E, after etching, a transparent conductive layer 112 is formed on the light-emitting region 110. The transparent conductive layer 112 can have high transmission rate and high electrical conductivity so that light can transmit therethrough and electrical current can be uniformly spread. Generally, the transparent conductive layer 112 can be formed on the light emitting region 110 using physical vapor deposition such as evaporation or sputtering. The material of the transparent conductive layer 112 can be nickel gold alloy, indium tin oxide, indium zinc oxide, indium tungsten oxide, or indium gallium oxide.

Referring to FIG. 11F, an n-type electrode 115 is formed on the transparent conductive layer 112 and electrically connected to the n-type conduction layer 104. The material of the n-type electrode 115 can be titanium/aluminum/titanium/gold, chrome-gold alloy, or lead-gold alloy.

Referring to FIG. 11G, a protection layer 116 is formed to cover the light emitting region 110 while exposing the n-type electrode 115, or formed to cover the light emitting region 110 and the protrusion structures 111a, 111b, and 111c while exposing the n-type electrode 115 so as to protect the light emitting region 110 from external pollutants or noise. The material of the protection layer 116 can be silicon oxide or silicon nitride.

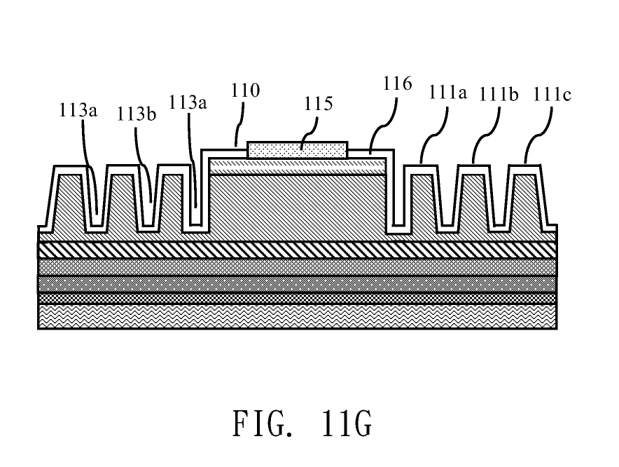

Two tests are performed to demonstrate the advantages of the devices of the present invention. One test is related to the luminosity comparison between the semiconductor optoelectronic device fabricated in accordance with the fabricating method of the present invention and the conventional semiconductor optoelectronic device fabricated according to the method disclosed in U.S. Patent Application No. 2007/0,228,393. FIG. 12 shows the luminous intensity distribution curves of the semiconductor optoelectronic device of one embodiment of the present invention and of the conventional semiconductor optoelectronic device, wherein the solid dot curve represents the semiconductor optoelectronic device of one embodiment of the present invention, while the circle dot curve represents the conventional semiconductor optoelectronic device. It can be seen that the luminosity of the device of the present invention is 5% higher than that of the conventional semiconductor optoelectronic device.

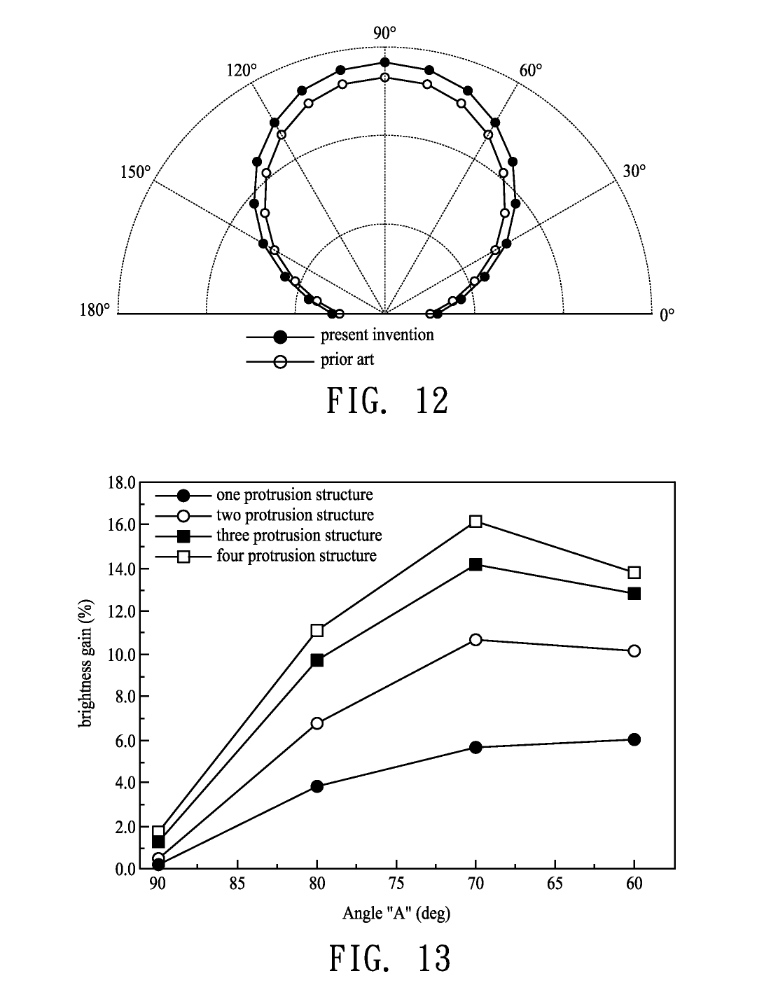

Another test is for verifying the number of protrusion structures and the inclined angle of their side surfaces. The protrusion structure disclosed in the present invention surrounds the light-emitting region. Because light transmits in a non-directional fashion, a portion of light is reflected or refracted through the protrusion structure(s). FIG. 13 is a diagram showing brightness gain vs. the inclined angle of side surface for the different quantities of protrusion structures. It can be seen that when the quantities of the protrusion structures increase, the brightness gain increases. Further, regarding the inclined angle change, when the quantity of protrusion structures around the light emitting region is one, the brightness gain of the protrusion structure with a side surface inclined at 60 degrees is 6% higher than that of the light emitting structure having no protrusion structure, and the protrusion structure with a side surface inclined at such an angle exhibits the highest brightness gain. When the quantity of protrusion structures is two, the protrusion structure with a side surface inclined at 70 degrees exhibits the highest brightness gain. Therefore, from the diagram of FIG. 13, it can be found that when the quantity of protrusion structures is four and the protrusion structure side surface is inclined at 70 degrees, the brightness gain is 15% higher than that of the light emitting structure having no protrusion structure.

Obviously, the two tests produce positive results. The structure of the present invention can increase light extraction efficiency, and can further reduce internal energy consumption.

The above-described embodiments of the present invention are intended to be illustrative only. Numerous alternative embodiments may be devised by persons skilled in the art without departing from the scope of the following claims.

What is claimed is:

1. A semiconductor optoelectronic device with enhanced light extraction efficiency, comprising:
a substrate;
a light emitting region, comprising:
an n-type conduction layer formed on said substrate;
a light emitting layer formed on said n-type conduction layer; and
a p-type conduction layer formed on said light emitting layer; and
a first protrusion structure disposed around said light emitting region and separated from said light emitting region by a first groove.

2. The semiconductor optoelectronic device with enhanced light extraction efficiency of claim 1, further comprising a buffer layer formed between said substrate and said n-type conduction layer.

3. The semiconductor optoelectronic device with enhanced light extraction efficiency of claim 2, further comprising a transparent conductive layer formed on said light emitting region.

4. The semiconductor optoelectronic device with enhanced light extraction efficiency of claim 1, further comprising a second protrusion structure, a third protrusion structure, and a fourth protrusion structure, wherein said second protrusion structure, said third protrusion structure, and said fourth protrusion structure are disposed around said light emitting region, are parallel to one another, and are separated from one another by a second groove and a third groove.

5. The semiconductor optoelectronic device with enhanced light extraction efficiency of claim 4, wherein each of said first, second and third grooves has a width in a range of from 0.1 to 10 micrometers.

6. The semiconductor optoelectronic device with enhanced light extraction efficiency of claim 5, wherein each of said first, second, third and fourth protrusion structures includes an inclined side surface.

7. The semiconductor optoelectronic device with enhanced light extraction efficiency of claim 5, wherein each of said first, second, third and fourth protrusion structures includes a trapezoidal or triangular cross section.

8. The semiconductor optoelectronic device with enhanced light extraction efficiency of claim 7, wherein said inclined side surface is inclined at an angle of from 45 to 90 degrees.

9. The semiconductor optoelectronic device with enhanced light extraction efficiency of claim 4, wherein each of said first, second, third, and fourth protrusion structures has a height between that of said p-type conduction layer and that of said n-type conduction layer.

10. The semiconductor optoelectronic device with enhanced light extraction efficiency of claim 9, wherein each of said first, second, third, and fourth protrusion structures has a width in a range of from 0.1 to 10 micrometers.

11. A method for forming a semiconductor optoelectronic device with enhanced light extraction efficiency, comprising the steps of:
providing a substrate;
forming a light emitting structure on said substrate, said light emitting structure comprising:
an n-type conduction layer formed on said substrate;
a light emitting layer formed on said n-type conduction layer; and
a p-type conduction layer formed on said light emitting layer; and
etching said light emitting structure peripherally to form a light emitting region and a first protrusion structure around said light emitting region.

12. The method of claim 11, further comprising a step of forming a buffer layer between said substrate and said n-type conduction layer.

13. The method of claim 11, further comprising a step of forming a second protrusion structure, a third protrusion structure, and a fourth protrusion structure, wherein said second protrusion structure, said third protrusion structure, and said fourth protrusion structure are disposed around said light emitting region, parallel to one another and separated from one another by a groove.

14. The method of claim 13, wherein said grooves have a width in a range of from 0.1 to 10 micrometers.

15. The method of claim 13, wherein each of said first, second, third, and fourth protrusion structures includes an inclined side surface.

16. The method of claim 15, wherein each of said first, second, third and fourth protrusion structures includes a trapezoidal or triangular cross section.

17. The method of claim 15, wherein said inclined side surface is inclined at an angle of from 45 to 90 degrees.

18. The method of claim 17, wherein said inclined side surface is inclined at an angle of from 65 to 80 degrees.

19. The method of claim 13, wherein each of said first, second, third, and fourth protrusion structures has a height between that of said p-type conduction layer and that of said n-type conduction layer.

20. The method of claim 13, wherein each of said first, second, third and fourth protrusion structures has a width in a range of from 0.1 to 10 micrometers.
